(19) United States
(12) Patent Application Publication
(10) Pub. No.: US 2026/0324337 A1
(43) Pub. Date: Oct. 15, 2026

(54) PURGING IN LOAD LOCK CHAMBERS

(71) Applicant: ASM IP Holding B.V., Almere (NL)

(72) Inventors: Masaei Suwada, Nagaoka-shi (JP); Taira Okabe, Kawasaki-shi (JP); Kazunori Furukawahara, Nagaoka-shi (JP); Hideki Yoshida, Tokyo (JP); Masashi Nakano, Tokyo (JP)

(21) Appl. No.: 19/641,760

(22) Filed: Apr. 8, 2026

Related U.S. Application Data
(60) Provisional application No. 63/787,228, filed on Apr. 11, 2025.

(51) Int. Cl. H10P 72/00; C23C 16/44

(52) U.S. Cl. CPC H10P 72/0402; C23C 16/4408; H10P 72/0466

(57) ABSTRACT

Removal of residues from surfaces of a wafer located in a load locked chamber or removal of contaminants from inside the load lock chamber via purging processes are disclosed. The systems disclosed include a load lock chamber, an injection system configured to provide purge gas into the load lock chamber, an exhaust system configured to remove gas from the load lock chamber, and a controller. The controller may remove contaminants and/or residues from the load lock chamber by controlling the injection system to provide the purge gas inside the load lock chamber to increase chamber pressure inside the load lock chamber, controlling the exhaust system to remove gas from the load lock chamber and decrease the chamber pressure, and then controlling the injection system to provide the purge gas inside the load lock chamber and increase the chamber pressure.

### CROSS-REFERENCE TO RELATED APPLICATIONS

This application claims priority to U.S. Provisional Patent Application Ser. No. 63/787,228 filed Apr. 11, 2025 titled PURGING IN LOAD LOCK CHAMBERS, the disclosure of which is hereby incorporated by reference in its entirety.

### FIELD

The present disclosure relates generally to the field of semiconductor processing methods and systems and to the field of device and integrated circuit manufacture. More particularly, the present disclosure generally relates to purging or removing contaminants in load locked chambers.

### BACKGROUND

In semiconductor manufacturing, wafers undergo various processing steps, which may result in residual process gases, segments, and byproducts being left on the surfaces of the wafers. When the wafers are later transferred to load locked chambers, the residues on the surfaces of the wafers may separate from the surfaces of the wafers. The separated residues or contaminants may attach to the inner walls of the load lock chambers and/or other components that are in fluid communications with the load lock chambers, thereby corroding or damaging the inner walls and/or the components. Therefore, it is desirable to remove the detached residues or contaminants to prevent corrosion or damage to the load lock chambers and not compromise the functionality and longevity of the load lock chambers. Such damage to the load lock chambers due to contaminations may lead to costly maintenance and potential downtime.

The residues or contaminants may be removed when the wafers are present in the process chambers by running one or more purging cycles in the process chambers. The purging cycles typically involve introducing a purge gas that helps expel the residues from the surfaces of the wafers. However, process chambers are characterized by large volumes. Therefore, the time taken to remove the residues may be considerable, which may impact the overall throughput of the semiconductor manufacturing process, slowing down production and affecting the efficiency of the operation.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to removing residues from the surfaces of wafers by transferring the wafer to load lock chambers and performing the purging process inside the load lock chambers to remove residues from the surfaces of the wafer or any expelled contaminants in the load locked chambers.

In accordance with examples of the disclosure, a load lock module may comprise a load lock chamber, at least one wafer holder configured to support a wafer in the load lock chamber, an injection system coupled with the load lock chamber and configured to provide purge gas into the load lock chamber, an exhaust system coupled with the load lock chamber and configured to remove gas from the load lock chamber, and a controller. The controller may be system to provide the purge gas inside the load lock chamber such that the chamber pressure inside the load lock chamber increases to a first level. The controller may then control the exhaust system to remove gas from the load lock chamber such that the chamber pressure decreases from the first level to a second level, and then control the injection system to provide the purge gas inside the load lock chamber such that the chamber pressure increases from the second level to a third level.

In accordance with examples of the disclosure, the exhaust system may comprise a first exhaust valve and a second exhaust valve, where the second exhaust valve may remove gas from the load lock chamber at a faster rate than the first exhaust valve. In accordance with examples of the disclosure, the controller may be configured to control the exhaust system to remove gas from the load lock chamber by turning on the first exhaust valve for a first time period to decrease the chamber pressure from the first level to an intermediate level, turning off the first exhaust valve, turning on the second exhaust valve for a second time period to decrease the chamber pressure from the intermediate level to the second level, and turning off the second exhaust valve. In accordance with examples of the disclosure, the second time period may be longer than the first time period. In accordance with examples of the disclosure, the controller may be further configured to, during a portion of the first time period or the second time period, control the injection system to provide the purge gas or an inert gas inside the load lock chamber.

In accordance with examples of the disclosure, the injection system may comprise a first injection valve and a second injection valve, where the second injection valve provides gas into the load lock chamber at a faster rate than the first injection valve. In accordance with examples of the disclosure, the controller may be configured to control the injection system to provide the purge gas inside the load lock chamber such that the chamber pressure increases to the first level or the third level by turning on the first injection valve. After the chamber pressure reaches an intermediate level, the controller may turn on the second injection valve to increase the chamber pressure from the intermediate level to the first level or the third level. After the chamber pressure reaches the first level or the third level, the controller may turn off the first injection valve and the second injection valve.

In accordance with examples of the disclosure, the first level of the chamber pressure inside the load lock chamber may be substantially equal to the third level, and the second level is lower than the first level and the third level.

In accordance with examples of the disclosure, the controller may be further configured to control the exhaust system to remove gas from the load lock chamber after the chamber pressure increases from the second level to the third level.

In accordance with examples of the disclosure, the load lock module may further comprise a first gate valve coupled to the load lock chamber and configured to allow transferring of the wafer between the load lock chamber and an Equipment Front End Module (EFEM). The controller may be configured to keep the first gate valve in a closed state while removing the contaminants from the load lock chamber.

In accordance with examples of the disclosure, the load lock module may comprise a second gate valve coupled to the load lock chamber and configured to allow the transferring of the wafer between the load lock chamber and a wafer handling chamber. Before removing the contaminants from the load lock chamber, the controller may be configured to set the second gate valve in an open state and transfer the wafer from the wafer handling chamber to the load lock chamber.

In accordance with examples of the disclosure, the purge gas may comprise molecular nitrogen, argon, or helium.

In accordance with examples of the disclosure, a method of removing contaminants from a load lock chamber may comprise providing a wafer inside the load lock chamber, providing a purge gas inside the load lock chamber such that a chamber pressure inside the load lock chamber increases to a first level, removing gas from the load lock chamber such that the chamber pressure decreases from the first level to a second level, and providing the purge gas inside the load lock chamber such that the chamber pressure increases from the second level to a third level.

In accordance with examples of the disclosure, removing gas from the load lock chamber may comprise turning on a first exhaust valve for a first time period to decrease the chamber pressure from the first level to an intermediate level, turning off the first exhaust valve, turning on a second exhaust valve for a second time period to decrease the chamber pressure from the intermediate level to the second level, and turning off the second exhaust valve. The second exhaust valve may remove gas from the load lock chamber at a faster rate than the first exhaust valve. In accordance with examples of the disclosure, the second time period may be longer than the first time period. In accordance with examples of the disclosure, removing gas from the load lock chamber may also comprise providing, during a portion of the first time period or the second time period, the purge gas or an inert gas inside the load lock chamber.

In accordance with examples of the disclosure, providing the purge gas inside the load lock chamber such that the chamber pressure increases to the first level or the third level may comprise turning on a first injection valve. After the chamber pressure reaches an intermediate level, a second injection valve may be turned on to increase the chamber pressure from the intermediate level to the first level or the third level, and after the chamber pressure reaches the first level or the third level, the first injection valve and the second injection valve may be turned off.

In accordance with examples of the disclosure, the method may further comprise removing gas from the load lock chamber after the chamber pressure increases from the second level to the third level.

In accordance with examples of the disclosure, the method may further comprise keeping a first gate valve, coupled to the load lock chamber and configured to allow the transferring of the wafer between the load lock chamber and an Equipment Front End Module (EFEM), in a closed state while removing the contaminants from the load lock chamber.

In accordance with examples of the disclosure, providing the wafer inside the load lock chamber may comprise setting a second gate valve, coupled to the load lock chamber, in an open state, transferring, via the second gate valve in the open state, the wafer from a wafer handling chamber to the load lock chamber, and setting the second gate valve in a closed state.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1A illustrates an example wafer treatment apparatus in accordance with one or more embodiments of the disclosure.

FIG. 1B illustrates another example wafer treatment apparatus in accordance with one or more embodiments of the disclosure.

FIG. 2 illustrates an example load lock module in accordance with one or more embodiments of the disclosure.

FIG. 3 is a flowchart illustrating an example of a method of purging a load lock chamber in accordance with one or more embodiments of the disclosure.

FIG. 4A illustrates example changes over time of chamber pressure in the load lock chamber during various stages of the example method of FIG. 3, in accordance with one or more embodiments of the disclosure.

FIG. 4B illustrates example statuses of different components of a load lock chamber during various stages of the example method of FIG. 3, in accordance with one or more embodiments of the disclosure.

FIG. 5 is a flowchart illustrating another example method of purging a load lock chamber in accordance with one or more embodiments of the disclosure.

FIG. 6A illustrates example changes over time of chamber pressure in the load lock chamber during various stages of the example method of FIG. 5, in accordance with one or more embodiments of the disclosure.

FIG. 6B illustrates example statuses of different components of a load lock chamber during various stages of the example method of FIG. 5, in accordance with one or more embodiments of the disclosure.

FIG. 7A illustrates a functional block diagram of a controller in accordance with one or more embodiments of the disclosure.

FIG. 7B illustrates a processing circuitry of a controller in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “wafer” can refer to any underlying material or materials that can be used to form, or upon which, a device, a circuit, or a film can be formed by means of a method according to an embodiment of the present disclosure. A wafer can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. The wafer can include various topologies, such as gaps, including recesses, lines, trenches or spaces between elevated portions, such as fins, and the like formed within or on at least a portion of a layer of the wafer. By way of example, a wafer can include bulk semiconductor material and an insulating or dielectric material layer overlying at least a portion of the bulk semiconductor material. Further, the term “wafer” may refer to any underlying material or materials that may be used, or upon which, a device, a circuit, or a film may be formed. The “wafer” may be continuous or non-continuous; rigid or flexible; solid or porous. The “wafer” may be in any form, such as a powder, a plate, or a workpiece. Wafers in the form of a plate may include wafers in various shapes and sizes. Wafers may be made from materials such as silicon, silicon germanium, silicon oxide, gallium arsenide, gallium nitride, and silicon carbide, for example. A continuous wafer may extend beyond the bounds of a process chamber where a deposition process occurs and may move through the process chamber such that the process continues until the end of the wafer is reached. A continuous wafer may be supplied from a continuous wafer feeding system, allowing for the manufacture and output of the continuous wafer in any appropriate form. Non-limiting examples of a continuous wafer may include a sheet, a non-woven film, a roll, a foil, a web, a flexible material, or a bundle of continuous filaments or fibers (i.e., ceramic fibers or polymer fibers). Continuous wafers may also comprise carriers or sheets upon which non-continuous wafers are mounted.

As used herein, the term “layer” can refer to any continuous or non-continuous structure and material. For example, a layer can include two-dimensional materials, three-dimensional materials, nanoparticles or even partial or full molecular layers or partial or full atomic layers or clusters of atoms and/or molecules. A layer may comprise material or a layer with pinholes, which may be at least partially continuous.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a wafer surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc., in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicated herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover the surface of the mentioned layer. Therefore, unless the term “directly” is separately used, the term “on” or “over” will be construed to be a relative concept. Similarly, to this, it will be understood the terms “under,” “underlying,” or “below” will be construed to be relative concepts.

When wafers are processed during the production of semiconductor devices, residues, such as residual process gases, segments, and byproducts, may be left on the surface of the wafer as a result of the processing. The residues may cause various types of contamination. First, self-contamination may result when the residues on the wafer react with the atmosphere and cause damage to the wafer itself, such as crystalline defects, mask erosion, or pattern collapse. Equipment contamination may result when the residues on the wafer react with the moisture in the atmosphere and cause outgassing, which may transfer to wafer handling equipment (e.g., the robotic arms used to transfer the wafers) or the components and/or inner walls of the load lock chamber. The residues or contaminants may then cause corrosive damage to the equipment over time.

Described herein are the removal processes of residues and/or contaminants from the surface of a wafer located in a load locked chamber and/or from inside the load lock chamber. The residues or contaminants may be removed via purging processes inside the load lock chamber. Removal of residues and/or contaminations from the load lock chamber may prevent corrosion and/or damage to the load lock chamber. Furthermore, residues from the surface of the wafer may be expelled, and the wafer may be prepared for the next phase of the semiconductor manufacturing process.

One of the significant advantages of performing the purging processes in the load lock chamber rather than in the process chambers is that the load lock chamber has a lower chamber volume compared to the process chambers. The load lock chamber's relatively small size may allow for several benefits that contribute to improved efficiency during the semiconductor manufacturing process. For example, the smaller volume of the load lock chamber may result in faster purging cycles, which may help minimize delays between steps in the overall production flow of the semiconductor manufacturing process, contributing to better system throughput and operational efficiency. With less volume to manage inside the load lock chambers, the purge gas can more effectively and quickly remove any residual outgassing from the wafer. The quicker and more efficient removal of residues and/or contaminations may reduce the likelihood of material degradation or corrosion inside the load lock chamber, thereby improving the longevity and reliability of the load lock module.

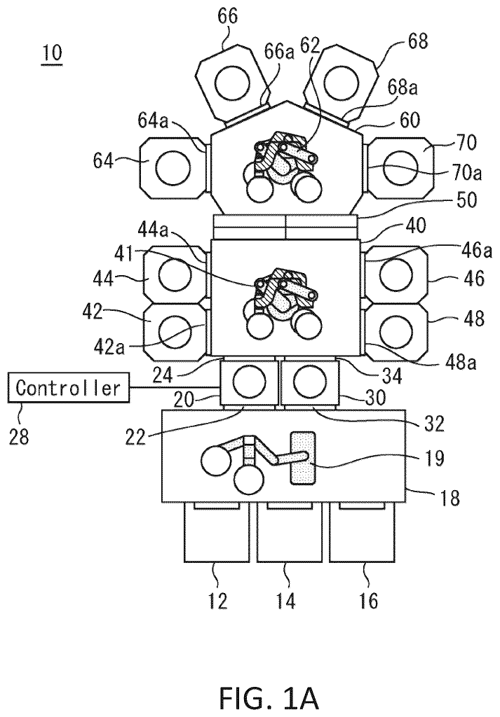

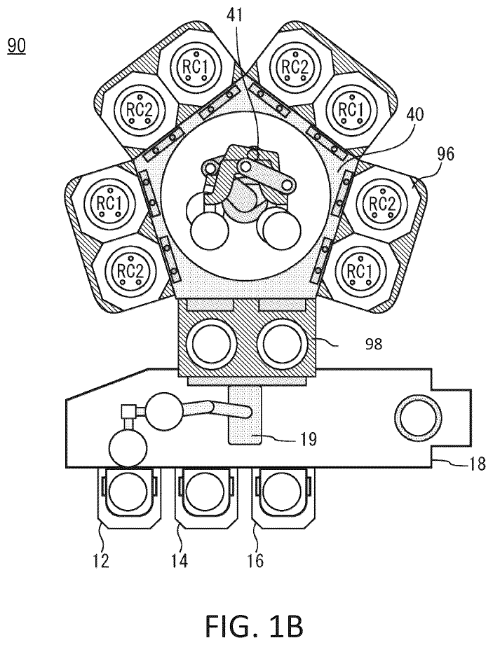

Turning now to the figures, FIG. 1A is a view showing a configuration example of a wafer treatment apparatus 10. This wafer treatment apparatus 10 may include a plurality of load ports. In the example of FIG. 1A, three load ports, load ports 12, 14, and 16, are present. The number of load ports in the wafer treatment apparatus 10 is set at three, but two, four, or more load ports may be present. A front-end module 18 may be provided adjacent to the plurality of load ports 12, 14, and 16. The front-end module 18 includes a Fan Filter Unit (FFU), which may be provided so as to transfer a wafer under atmospheric pressure. The front-end module 18 may include a first wafer transfer device 19. According to one example, the first wafer transfer device 19 may be a robot for transferring the wafer. The load ports 12, 14, and 16, the front-end module 18, and the first wafer transfer device 19 may be collectively referred to as an Equipment Front End Module (EFEM) or enclosure.

A first load lock chamber (first LLC) 20 and a second load lock chamber (second LLC) 30 may be provided adjacent to the front-end module 18. The first LLC 20 and the second LLC 30 may be connected to a vacuum device, and can be set to atmospheric pressure or vacuum. According to one example, the first LLC 20 and the second LLC 30 may be two independent chambers, and the movement of gas from one to the other is prevented. For information, in FIG. 1A, two load lock chambers are provided, but three or more load lock chambers may be provided. A gate valve 22 may be provided between the first LLC 20 and the front-end module (FEM) 18. A gate valve 32 may be provided between the second LLC 30 and the FEM 18.

A wafer handling chamber (WHC) 40 may be provided adjacent to a load lock module comprising the first LLC 20 and the second LLC 30. There may be a second wafer transfer device 41 in the WHC 40. According to one example, the second wafer transfer device 41 may be a robot for transferring wafers. A gate valve 24 may be provided between the first LLC 20 and the WHC 40. A gate valve 34 may be provided between the second LLC 30 and the WHC 40. Process chambers 42, 44, 46, and 48 may be adjacent to the WHC 40 via gate valves 42a, 44a, 46a, and 48a, respectively.

The WHC 40 may be in contact with the WHC 60 via a pass-through chamber 50. According to one example, the pass-through chamber 50 may include an upper pass-through chamber having a gate valve on the WHC 60 side and a lower pass-through chamber having a gate valve on the WHC 40 side. In other words, in the upper pass-through chamber and also in the lower pass-through chamber, there may be one gate valve between the WHC 40 and the WHC 60. Thereby, the pressures of the WHC 40 and the WHC 60 can be made different from each other. A third wafer transfer device 62 may be provided in the WHC 60. According to one example, each of the second wafer transfer devices 41 and the third wafer transfer device 62 may have two perpendicularly arranged arms. According to another example, the number of arms can be any number.

Process chambers 64, 66, 68, and 70 may be adjacent to the WHC 60 via gate valves 64a, 66a, 68a, and 70a, respectively. According to one example, the process chambers 42, 44, 46, and 48 and the process chambers 64, 66, 68, and 70 may be provided as apparatuses for forming an epitaxial growth film on the wafer by single-wafer treatment, such as by chemical vapor atomic layer deposition, atomic layer epitaxy (ALE), molecular beam epitaxy (MBE), gas source MBE, organometallic MBE, or chemical beam epitaxy. Layers may be grown on wafers by providing alternating pulses of precursor(s)/reactive gas(es), and purge (e.g., inert carrier) gas(es) in the reactor chambers.

A controller 28 may control wafer transport and wafer treatment in the wafer treatment apparatus 10. According to one example, the controller 28 manages a job list, issues a command for the transport of the wafer, and issues a command for wafer treatment. For information, the wafer can be transported along a transport path of the wafer, which a control job has designated.

The wafer treatment apparatus 10 of FIG. 1A can be configured differently. According to one example, the pass-through chamber 50, WHC 60, and process chambers 64, 66, 68, and 70 may be omitted. According to another example, the process chamber for single-wafer treatment can be replaced by a Dual Chamber Module (DCM) or a Quad Chamber Module (QCM), or replaced by another batch treatment chamber.

FIG. 1B illustrates an example of another wafer treatment apparatus 90. The wafer treatment apparatus 90 may include four DCMs 96 that are in contact with the WHC 40 and have two chambers. The wafer treatment apparatus 90 may also include a load lock chamber 98 comprising one or more wafer supports to support wafers.

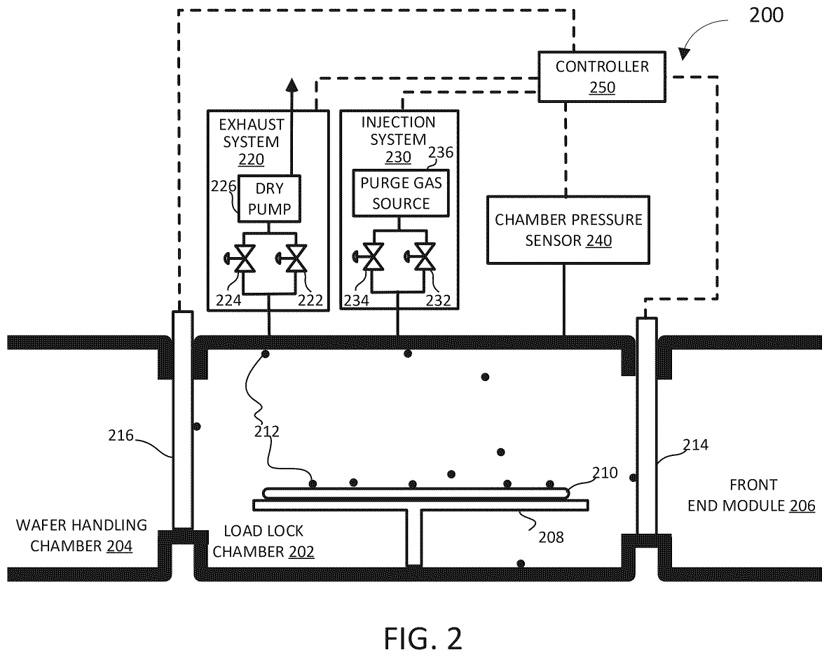

FIG. 2 shows a more detailed side view of an exemplary load lock module 200 comprising a load lock chamber 202 (e.g., the load lock chamber 20, 30, or 98) together with related components. The load lock chamber 202 may comprise a wafer holder 208, which may be configured to support a wafer 210. Residues 212 may be attached to the surface of the wafer 210. Some of the residues 212 may detach from the surface of the wafer 210, attach to the inner walls of the load lock chamber 202, the gate valves 214 and 216, and/or other components coupled to the load lock chamber 202. The detached residues may cause corrosion to the inner walls, the gate valves, and/or the components of the load lock chamber 202. Residues that stay attached to the wafer may damage the wafer itself.

The load lock chamber 202 may also comprise or be coupled to a gate valve 216 (e.g., gate valve 24 or 34). When the gate valve 216 is in an open state, there may be fluid communication between the load lock chamber 202 and the WHC 204 (e.g., WHC 40). When the gate valve 216 is in closed state, there is no fluid communication between the load lock chamber 202 and the WHC 204. When the gate valve 216 is in an open state, a wafer may be transferred to the load lock chamber 202 from a process chamber (e.g., process chamber 42, 44, 46, 48, 64, 66, 68, or 70), the WHC 40, or the WHC 60. Additionally, when the gate valve 216 is in an open state, a wafer may be transferred from the load lock chamber 202 to a process chamber (e.g., process chamber 42, 44, 46, 48, 64, 66, 68, or 70), the WHC 40, or the WHC 60.

The load lock chamber 202 may also comprise or be coupled to another gate valve 214 (e.g., the gate valve 22 or 32). When the gate valve 214 is in an open state, there may be fluid communication between the load lock chamber 202 and the front-end module 206 (e.g., the front-end module 18). When the gate valve 214 is in closed state, there is no fluid communication between the load lock chamber 202 and the front-end module 206. When the gate valve 214 is in an open state, a wafer may be transferred to the load lock chamber 202 from the front-end module 206 or a load port (e.g., load ports 12, 14, or 16). Additionally, when the gate valve 214 is in an open state, a wafer may be transferred from the load lock chamber 202 to the front-end module 206 or a load port.

Additionally, the load lock chamber 202 may be coupled to an exhaust system 220 configured to remove gas from the load lock chamber 202. The exhaust system 220 comprises a dry pump 226 connected to the load lock chamber 202 via both a slow exhaust valve 222 and a fast exhaust valve 224. A purging process inside the load lock chamber 202 may require that the pressure within a chamber be varied between relatively high and relatively low pressures. When pumping down the load lock chamber 202 from a relatively high pressure to a relatively low pressure, the pump-down rate is preferably not so large as to cause undesirable turbulence, which can stir up particles within the load lock chamber 202 or within the piping network attached to the load lock chamber 202. Such turbulence or stirring up of particles is undesirable because these events can contaminate or otherwise adversely affect the quality of the wafer 210. To avoid such undesirable turbulence, a process chamber pump-down may typically occur in two steps. First, the pump-down may be started by turning on the slow exhaust valve 222 comprising a small orifice valve. The small size of the opening of the slow exhaust valve 222 limits the rate at which gas can exit the load lock chamber 202. Slow removal of gas via the slow exhaust valve 222 may aid in minimizing both gas turbulence and the stirring up of particles in the wafer 210. After pumping through the slow exhaust valve 222 for some time or after reaching a particular chamber pressure, a fast exhaust valve 224 comprising a larger opening valve is opened to complete the pump-down. In some examples, the gas flow at the slow exhaust valve 222 may be from 0.1 to 15 SLM, while the gas glow at the fast exhaust valve 224 may be from 15 to 50 SLM.

The load lock chamber 202 may be further coupled to an injection system 230 that injects purge gas into the load lock chamber 202. The purge gas may be provided by the purge gas source 236. An exemplary purge gas source 236 may include one or more individual gas tanks comprising nitrogen, argon, helium, carbon dioxide, and/or other inert gasses. The purge gas source 236 may be coupled to the load lock chamber 202 via two valves, a slow injection valve 232 and a fast injection valve 234. When pumping up the load lock chamber 202 from a relatively low pressure to a relatively high pressure, the pump-up rate is preferably not so large as to cause undesirable turbulence. Therefore, the pump-up process in the load lock chamber may occur in two steps, similar to the pump-down process described above. First, the pump-up process may be started by turning on the slow injection valve 232 comprising a small orifice valve. The small size of the opening of the slow injection valve 232 limits the rate at which gas can enter the load lock chamber 202. After pumping gas into the load lock chamber 202 through the slow injection valve 232 for some time or after reaching a particular chamber pressure, the fast injection valve 234, comprising a larger opening valve, is opened to complete the backfill in the load lock chamber 202 with a purge gas. In some examples, the gas flow at the slow injection valve 232 may be from 0.1 to 15 SLM, while the gas glow at the fast injection valve 234 may be from 15 to 50 SLM.

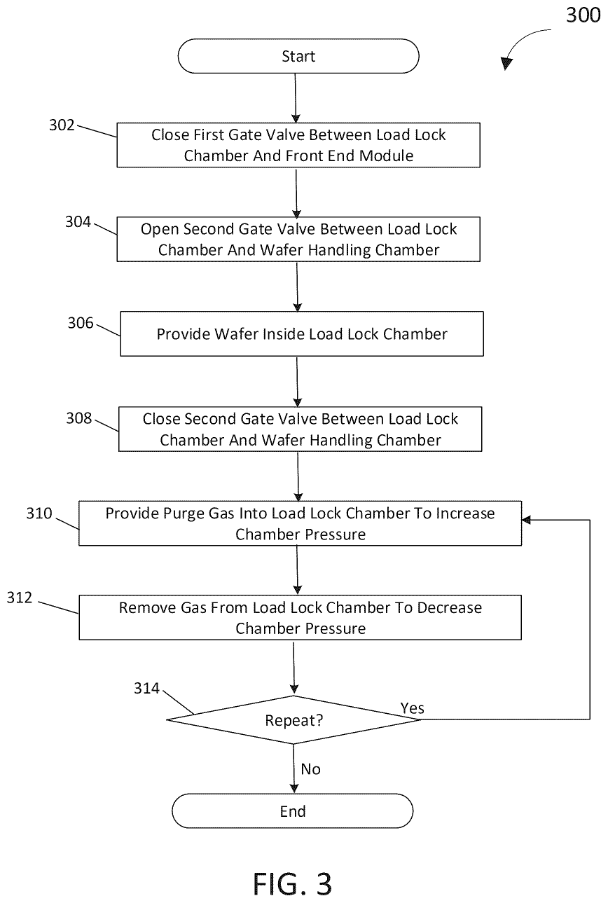

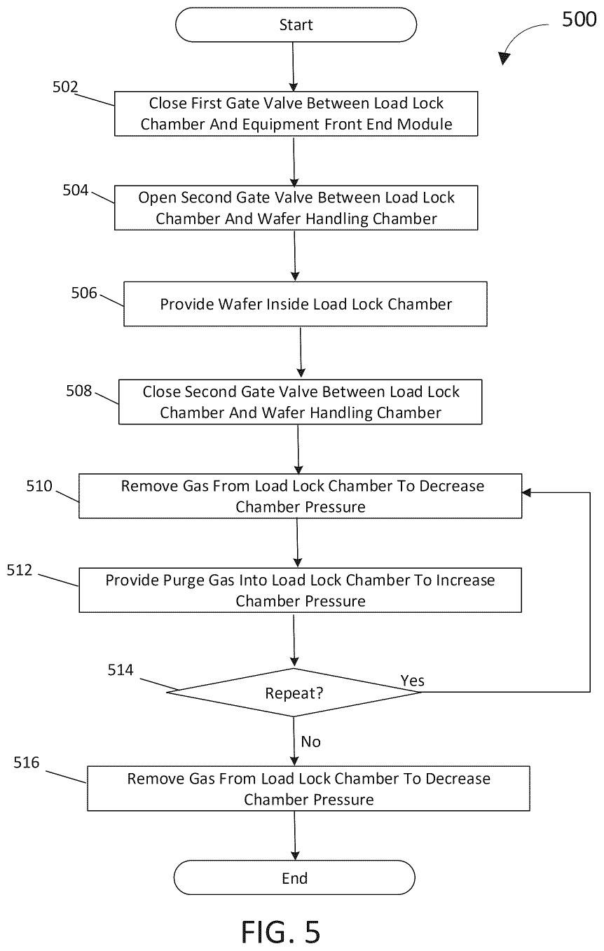

A chamber pressure sensor 240 may be coupled to the load lock chamber 202 and configured to measure the pressure inside the load lock chamber 202. A controller 250 is shown connected to the pressure sensor 240, the exhaust system 220 (e.g., to the slow exhaust valve 222, the fast exhaust valve 224), the injection system 230 (e.g., to the slow injection valve 232, the fast injection valve 234), the gate valve 214, and/or the gate valve 216. The controller 250 may be configured to open and close the gate valve 214 and/or the gate valve 216, turn on or off the slow exhaust valve 222 and/or the fast exhaust valve 224 to remove gas from the load lock chamber 202, and turn on or off the slow injection valve 232 and the fast injection valve 234 to provide purge gas inside the load lock chamber 202. The controller may be configured to perform the methods in FIG. 3 and FIG. 5, as described below.

FIG. 3 illustrates a flowchart 300 describing an example method of purging a load lock chamber (e.g., the load lock chamber 202) in accordance with one or more embodiments of the disclosure. The steps in the flowchart 300 may be performed by a controller (e.g., controller 28 or 250) coupled to the load lock chamber or a wafer treatment apparatus hosting a load lock chamber (e.g., wafer treatment apparatus 10 or 20).

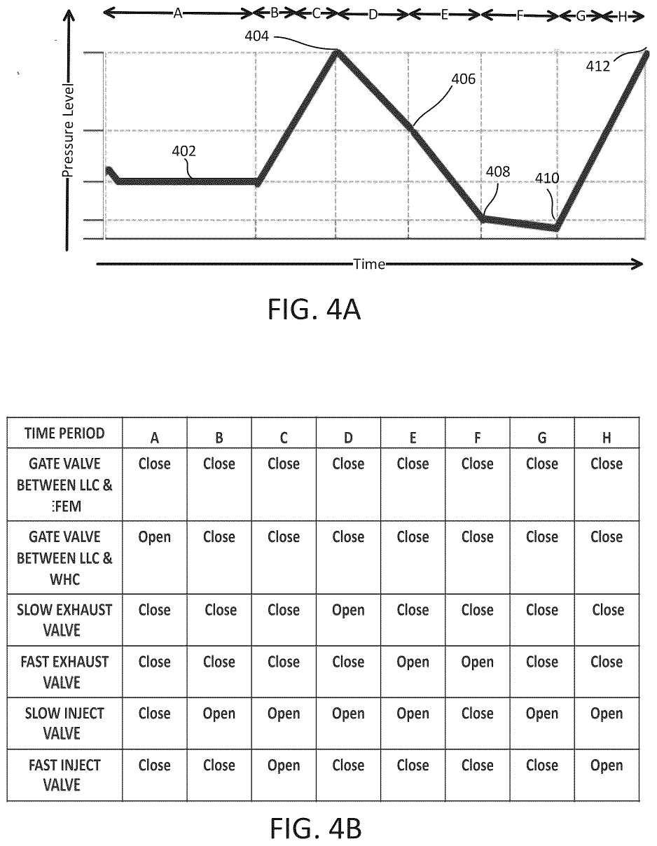

At step 302 of the flowchart 300, a first gate valve (e.g., the gate valve 214) between the load lock chamber and a front-end module adjacent to the load lock chamber (e.g., front-end module 18 or 206) may be closed. At step 304, a second gate valve (e.g., the gate valve 216) between the load lock chamber and a wafer handling chamber adjacent to the load lock chamber (e.g., wafer handling chamber 40 or 204) may be opened. At step 306, a wafer may be transferred from the wafer handling chamber to the load lock chamber via the open gate valve. The wafer may be deposited in a wafer holder (e.g., wafer holder 208) inside the load lock chamber. After the wafer is provided inside the load lock chamber at step 306, the second gate valve may be closed at step 308. After the second gate valve is closed, the chamber pressure inside the load lock chamber may be at the same level or substantially the same level as the pressure inside the wafer handling chamber. For example, FIG. 4A illustrates example changes over time of chamber pressure in the load lock chamber, while FIG. 4B illustrates example statuses of different components of a load lock chamber. During the time period A, after the wafer is transferred to the load lock chamber and after the second gate valve is closed, the chamber pressure inside the load lock chamber may be at a starting level 402 (e.g., the chamber pressure level of the wafer handling chamber).

Referring back to FIG. 3, at step 310, a purge gas may be provided into the load lock chamber, such that the chamber pressure inside the load lock chamber increases from the starting level to a first level. For example, as shown in FIG. 4A, during time periods B and C, the chamber pressure increases from the starting level 402 to the first level 404. Providing the purge gas into the load lock chamber may comprise opening a slow injection valve (e.g., the slow injection valve 232), a fast injection valve (e.g., the fast injection pump 234), or both. For example, as shown in FIG. 4B, during the time period B, the slow injection valve may be opened. The time period A may be 1 to 10 seconds long. At the end of time period B, the chamber pressure inside the load lock chamber may be at a crossover level. After the chamber pressures cross the crossover level, the time period C may begin where the fast injection valve may be opened while the slow injection valve is still open. Alternatively, the fast injection valve may be opened at the beginning of time period C regardless of whether the chamber pressure inside the load lock chamber crosses the crossover level or not. The time period B may be 1 to 10 seconds long. The slow injection valve may have a flow rate of 0.1-10 SLM, while the fast injection valve may have a flow rate of 10-50 SLM. At the end of the time period C, both the slow injection valve and the fast injection valve may be closed.

Referring back to FIG. 3, at step 312, gas may be removed from the load lock chamber, such that the chamber pressure inside the load lock chamber decreases from the first level to a second level. For example, as shown in FIG. 4A, during time periods D, E, and F, the chamber pressure decreases from the first level 404 to the second level 410. Removing gas from the load lock chamber may comprise opening a slow exhaust valve (e.g., the slow exhaust valve 222), a fast exhaust valve (e.g., the fast exhaust valve 224), or both. For example, as shown in FIG. 4B, during time period D, the slow exhaust valve may be opened. The time period D may be 1 to 20 seconds long. During the time period D, the slow injection valve may also be open to allow a purge gas (e.g., nitrogen, argon, helium, or carbon dioxide) at a flow rate of 0.1 to 10 SLM. At the end of time period D, the chamber pressure inside the load lock chamber may be at a first intermediate level 406. After the chamber pressure crosses the first intermediate level 406, the time period E may begin where the fast exhaust valve may be opened while the slow exhaust valve is still open. Alternatively, the fast exhaust valve may be opened at the beginning of time period E regardless of whether the chamber pressure inside the load lock chamber crosses the first intermediate level 406 or not. The time period E may be 1 to 10 seconds long. During the time period E, the slow injection valve may also be open to allow purge gas inside the load lock chamber at a flow rate of 0.1 to 10 SLM. At the end of time period E, the chamber pressure inside the load lock chamber may be at a second intermediate level 408, such that at the beginning of time period F, the fast exhaust valve may be kept open. In contrast, during the time period F, the slow exhaust valve may be closed. The time period F may be 0.1 to 10 seconds long. During time period F, the slow injection valve may be closed. While gas is removed from the load lock chamber, the slow exhaust valve may have a flow rate of 1-10 SLM, while the fast exhaust valve may have a flow rate of 10-50 SLM. At the end of time period F, both the slow exhaust valve and the fast exhaust valve may be closed, and the gas pressure may reach the second level 410.

Referring back to FIG. 3, steps 310 and 312 may constitute one purging cycle. At step 314, it may be determined whether the purging cycle needs to be repeated. If another purging cycle is needed, then the method may continue to step 310. For example, as shown in FIG. 4A, during time periods G and H, the chamber pressure increases from the second level 410 to the third level 412. The third level may be substantially the same as the first level 404 or different (e.g., higher or lower). The chamber pressure may be increased to the third level 412 by opening and closing the slow injection valve and the fast injection valve in the same sequence performed during the time periods B and C. Referring back to FIG. 3, at step 314, if it is determined that no more purging cycles are needed, the method ends.

FIG. 5 is a flowchart illustrating another example method of purging a load lock chamber (e.g., the load lock chamber 202) in accordance with one or more embodiments of the disclosure. The steps in the flowchart 500 may be performed by a controller (e.g., the controller 28 or 250) coupled to the load lock chamber or a wafer treatment apparatus hosting a load lock chamber (e.g., wafer treatment apparatus 10 or 20).

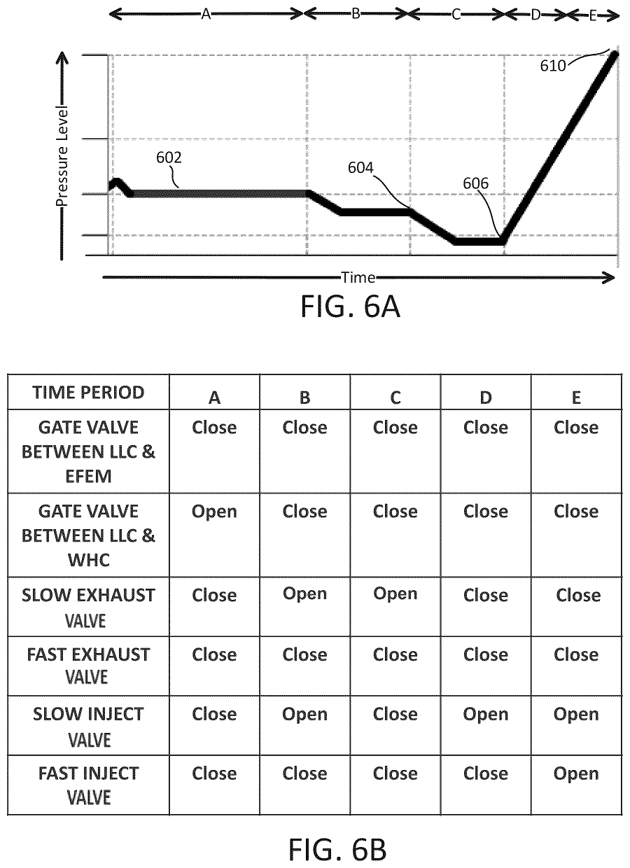

Steps 502, 504, 506, and 508 of the flowchart 500 may be similar to steps 302, 304, 306, and 308 of the flowchart 300 of FIG. 3, and therefore, details of steps 502, 504, 506, and 508 of the flowchart 500 are omitted herein. After the first gate valve and the second gate valve are both closed, the chamber pressure inside the load lock chamber may be at the same level or substantially the same level as the pressure inside the wafer handling chamber. For example, FIG. 6A illustrates example changes over time of chamber pressure in the load lock chamber during the different steps of flowchart 500, while FIG. 6B illustrates example statuses of different components of a load lock chamber. As shown in FIG. 6A and FIG. 6B, during time period A, while the first gate valve (e.g., the gate valve between the load lock chamber (LLC) and front end module) and the second gate valve (e.g., the gate valve between the LLC and the wafer handling chamber) are closed, the chamber pressure inside the load lock chamber may be at a starting level 602 (e.g., the chamber pressure level of the wafer handling chamber).

Referring back to FIG. 5, at step 510, gas may be removed from the load lock chamber, such that the chamber pressure inside the load lock chamber decreases from the starting level to a first level. For example, as shown in FIG. 6A, during time periods B and C, the chamber pressure decreases from the starting level 602 to the first level 606. Removing gas from the load lock chamber may comprise opening a slow exhaust valve (e.g., the slow exhaust valve 222), a fast exhaust valve (e.g., the fast exhaust valve 224), or both. For example, as shown in FIG. 6B, during time period B, the slow exhaust valve may be opened. The time period B may be 1 to 20 seconds long. During time period B, the slow injection valve may also be open to allow a purge gas (e.g., nitrogen, argon, helium, or carbon dioxide) at a flow rate of 0.1 to 10 SLM. At the end of time period B, the chamber pressure inside the load lock chamber may be at a first intermediate level 604, such that at the beginning of the time period C, the fast exhaust valve may be opened. The slow exhaust valve may still be open during the time period C. Alternatively, the fast exhaust valve may be opened at the beginning of time period C regardless of whether the chamber pressure inside the load lock chamber crosses the first intermediate level or not. The time period C may be 1 to 10 seconds long. During the time period C, the slow injection valve may be closed. At the end of time period C, the chamber pressure inside the load lock chamber may be at the first level 606. While gas is removed from the load lock chamber, the slow exhaust valve may have a flow rate of 1-10 SLM, while the fast exhaust valve may have a flow rate of 10-50 SLM. At the end of time period C, both the slow exhaust valve and the fast exhaust valve may be closed.

Referring back to FIG. 5, at step 512, a purge gas may be provided into the load lock chamber, such that the chamber pressure inside the load lock chamber increases from the first level to a second level. For example, as shown in FIG. 6A, during time periods D and E, the chamber pressure increases from the first level 606 to the second level 610. Providing the purge gas into the load lock chamber may comprise opening a slow injection valve (e.g., the slow injection valve 232), a fast injection valve (e.g., the fast injection pump 234), or both. For example, as shown in FIG. 6B, during time period D, the slow injection valve may be opened. The time period D may be 1 to 10 seconds long. At the end of time period D, the chamber pressure inside the load lock chamber may be at a crossover level, such that at the beginning of time period E, the fast injection valve may be opened while the slow injection valve is still open. Alternatively, the fast injection valve may be opened at the beginning of time period E regardless of the chamber pressure inside the load lock chamber. The time period E may be 1 to 10 seconds long. The slow injection valve may have a flow rate of 0.1-10 SLM, while the fast injection valve may have a flow rate of 10-50 SLM. At the end of time period E, both the slow injection valve and the fast injection valve may be closed.

Referring back to FIG. 5, steps 510 and 512 may constitute one purging cycle. At step 514, it may be determined whether the purging cycle needs to be repeated. If another purging cycle is needed, then the method may continue to step 510. If it is determined that no more purging cycles are needed, another gas removal step 514, similar to step 510, may be performed before the method ends.

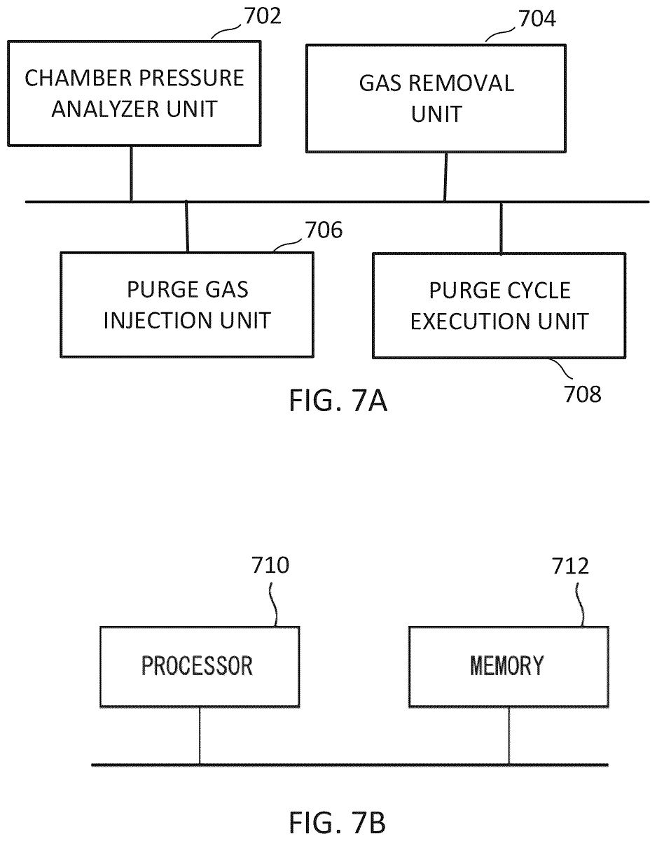

FIG. 7A is a functional block diagram of the above-described controller (e.g., controller 28 or 250). The controller may function as a chamber state controller, which controls the state of the load lock chamber. The controller may comprise a chamber pressure analyzer unit 702, which is a portion that acquires information about the pressure level inside a load lock chamber from one or more sensors (e.g., chamber pressure sensor 240) coupled to the load lock chamber. A purge cycle execution unit 708 is a portion that executes the processing of steps 302, 304, 306, 308, 310, 312, and 314 in FIG. 3 and/or processing of steps 502, 504, 506, 508, 510, 512, 514, and 516 in FIG. 5. The gas removal unit 704 may be controlled by the purge cycle execution unit when processing step 312 in FIG. 3 and steps 510 or 516 in FIG. 5. The gas removal unit 704 may receive information about the pressure level inside a load locked chamber from the chamber pressure analyzer unit 702 and control the opening and/or closing of slow exhaust valves and fast exhaust valves described above and turn on and off of the dry pump described above. The purge gas injection unit 706 may be controlled by the purge cycle execution unit when processing step 310 in FIG. 3 and step 512 in FIG. 5. The purge gas injection unit 706 may receive information about the pressure level inside a load locked chamber from the chamber pressure analyzer unit 702 and control the opening and closing of slow injection valves and fast injection valves described above.

The controller described above may comprise processing circuits. Each of the above-described functions, which is performed in a controller, may be realized by at least one processing circuit. Specifically, with the aid of the processing circuit, the controller performs one or more purging cycles in a load locked chamber. The processing circuit may be provided as dedicated hardware (dedicated circuit), or may be a CPU (a central processing unit, a processing device, an arithmetic device, a microprocessor, a microcomputer, a processor, or a DSP) which executes a program stored in a memory. The processing circuit may correspond to, for example, a single circuit, a composite circuit, a programmed processor, a parallel programmed processor, an ASIC, an FPGA, or a combination thereof. Each of the processes to be performed by the controller may be realized by a separate processing circuit or may be realized collectively by a processing circuit. FIG. 7B shows a configuration example of the controller in the case where the processing circuit is a CPU. In this case, each of the functions of the controller may be realized by software or a combination of software and firmware. The software or the firmware may be described as a program and may be stored in a memory 710. A processor 712 may read out and execute the program stored in the memory 710, and thereby realize each of the functions. In other words, the controller may include the memory 710 that stores the program, which results in executing each of the above-described steps when the processing circuit executes the program. The memory may correspond to, for example, a nonvolatile or volatile semiconductor memory such as a RAM, a ROM, a flash memory, an EPROM and an EEPROM; a magnetic disk; a flexible disk; an optical disk; a compact disk; a mini disk; or a DVD. As a matter of course, it is also acceptable to realize a part of each of the above functions by hardware, and realize a part of the functions by software or firmware. In this way, each of the above-described functions is executed by execution of the program stored in the memory by the processor, or by processing of a dedicated circuit.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A load lock module comprising:
a load lock chamber;
at least one wafer holder configured to support a wafer in the load lock chamber;
an injection system coupled with the load lock chamber and configured to provide purge gas into the load lock chamber;
an exhaust system coupled with the load lock chamber and configured to remove gas from the load lock chamber; and
a controller configured to remove contaminants from the load lock chamber by:
controlling the injection system to provide the purge gas inside the load lock chamber such that a chamber pressure, inside the load lock chamber, increases to a first level;
controlling the exhaust system to remove gas from the load lock chamber such that the chamber pressure decreases from the first level to a second level; and
controlling the injection system to provide the purge gas inside the load lock chamber such that the chamber pressure increases from the second level to a third level.

2. The load lock module of claim 1, wherein the exhaust system comprises:
a first exhaust valve; and
a second exhaust valve configured to allow gas to be removed from the load lock chamber at a faster rate than the first exhaust valve.

3. The load lock module of claim 2, wherein the controller is configured to control the exhaust system to remove gas from the load lock chamber by:
turning on the first exhaust valve for a first time period to decrease the chamber pressure from the first level to an intermediate level;
turning off the first exhaust valve;
turning on the second exhaust valve for a second time period to decrease the chamber pressure from the intermediate level to the second level; and
turning off the second exhaust valve.

4. The load lock module of claim 3, wherein the second time period is longer than the first time period.

5. The load lock module of claim 3, wherein the controller is further configured to, during a portion of the first time period or the second time period, control the injection system to provide the purge gas inside the load lock chamber.

6. The load lock module of claim 1, wherein the injection system comprises:
a first injection valve; and
a second injection valve that allows a provision of the purge gas into the load lock chamber at a faster rate than the first injection valve.

7. The load lock module of claim 6, wherein the controller is configured to control the injection system to provide the purge gas inside the load lock chamber such that the chamber pressure increases to the first level or the third level by:
turning on the first injection valve;
after the chamber pressure reaches an intermediate level, turning on the second injection valve to increase the chamber pressure from the intermediate level to the first level or the third level; and
after the chamber pressure reaches the first level or the third level, turning off the first injection valve and the second injection valve.

8. The load lock module of claim 1, wherein the first level is substantially equal to the third level, and wherein the second level is lower than the first level and the third level.

9. The load lock module of claim 1, wherein the controller is further configured to control the exhaust system to remove gas from the load lock chamber after the chamber pressure increases from the second level to the third level.

10. The load lock module of claim 1, further comprising a first gate valve coupled to the load lock chamber and configured to allow transferring of the wafer between the load lock chamber and an Equipment Front End Module (EFEM),
wherein the controller is configured to keep the first gate valve in a closed state while removing the contaminants from the load lock chamber.

11. The load lock module of claim 1, further comprising a second gate valve coupled to the load lock chamber and configured to allow transferring of the wafer between the load lock chamber and a wafer handling chamber,
wherein the controller is configured to, before removing the contaminants from the load lock chamber:
set the second gate valve in an open state; and
transfer the wafer from the wafer handling chamber to the load lock chamber.

12. The load lock module of claim 1, wherein the purge gas comprises molecular nitrogen (N₂) or an inert gas.

13. A method of removing contaminants from a load lock chamber, the method comprising:
providing a wafer inside the load lock chamber;
providing a purge gas inside the load lock chamber such that a chamber pressure, inside the load lock chamber, increases to a first level;
removing gas from the load lock chamber such that the chamber pressure decreases from the first level to a second level; and
providing the purge gas inside the load lock chamber such that the chamber pressure increases from the second level to a third level.

14. The method of claim 13, wherein the removing gas from the load lock chamber comprises:
turning on a first exhaust valve for a first time period to decrease the chamber pressure from the first level to an intermediate level;
turning off the first exhaust valve;
turning on a second exhaust valve for a second time period to decrease the chamber pressure from the intermediate level to the second level, wherein the second exhaust valve removes gas from the load lock chamber at a faster rate than the first exhaust valve; and
turning off the second exhaust valve.

15. The method of claim 14, wherein the second time period is longer than the first time period.

16. The method of claim 14, further comprising providing, during a portion of the first time period or the second time period, the purge gas or an inert gas inside the load lock chamber.

17. The method of claim 13, wherein the providing the purge gas inside the load lock chamber such that the chamber pressure increases to the first level or the third level comprises:
turning on a first injection valve;
after the chamber pressure reaches an intermediate level, turning on a second injection valve to increase the chamber pressure from the intermediate level to the first level or the third level; and
after the chamber pressure reaches the first level or the third level, turning off the first injection valve and the second injection valve.

18. The method of claim 13, further comprising:
removing gas from the load lock chamber after the chamber pressure increases from the second level to the third level.

19. The method of claim 13, further comprising:
keeping a first gate valve, coupled to the load lock chamber and configured to allow transferring of the wafer between the load lock chamber and a Front-End Module (FEM), in a closed state while removing the contaminants from the load lock chamber.

20. The method of claim 13, wherein the providing the wafer inside the load lock chamber comprises:
setting a second gate valve, coupled to the load lock chamber, in an open state;
transferring, via the second gate valve in the open state, the wafer from a wafer handling chamber to the load lock chamber; and
setting the second gate valve in a closed state.
